(19) United States
(12) Patent Application Publication
(10) Pub. No.: US 2012/0018818 A1
(43) Pub. Date: Jan. 26, 2012

(54) MEMS APPARATUS

(75) Inventor: Tomohiro Saito, Kanagawa-ken (JP)

(73) Assignee: KABUSHIKI KAISHA TOSHIBA, Tokyo (JP)

(21) Appl. No.: 13/184,666

(22) Filed: Jul. 18, 2011

(30) Foreign Application Priority Data
Jul. 20, 2010 (JP) 2010-162913

(51) Int. Cl. H01L 27/20; H01L 29/84

(52) U.S. Cl. 257/415; 257/E29.324; 257/E27.006

(57) ABSTRACT

According to an embodiment of the present invention, a MEMS apparatus includes a plurality of recesses opened to a surface, a substrate having an insulator, an air gap, or an insulator and an air gap formed in the recesses, an insulating layer formed on the substrate, and a MEMS device having a signal line formed on the insulating layer, wherein the position of the signal line in a direction parallel to the surface of the substrate overlaps the position of the recess in the direction.

### CROSS-REFERENCE TO RELATED APPLICATION

This application is based upon and claims the benefit of priority from prior Japanese Patent Application No. 2010-162913, filed on Jul. 20, 2010, the entire contents of which are incorporated herein by reference.

### FIELD

Embodiments of the present invention relate to a MEMS apparatus.

### BACKGROUND

There has been known a micro electromechanical part functioning as a capacitor, a switch, or the like in the prior art, the part including an insulating layer having a groove structural portion on a substrate, a functional device formed on the groove structural portion in the insulating layer, and a wiring for a signal. In such a micro electromechanical part, there are grooves under the functional device and the wiring for a signal, thereby reducing a parasitic capacitance between the functional device and the substrate and between the wiring for a signal and the substrate, so as to enhance high frequency characteristics.

However, since the functional device and the wiring for a signal are formed immediately above the groove structural portion in such a micro electromechanical part, flexure is liable to occur, thereby potentially hampering operation. In addition, unevenness is liable to occur at the surface of the groove structural portion, thereby making it difficult to secure the flatness and homogeneity of the wiring for a signal formed immediately above the groove structural portion.

Moreover, in order to effectively reduce the parasitic capacitance, the groove structural portion need be formed deeply. Therefore, the insulating layer need be increased in thickness. However, the increase in thickness of the insulating layer is likely to induce flexure on the substrate due to a difference in stress between the insulating layer and the substrate.

### BRIEF DESCRIPTION OF THE DRAWINGS

FIG. 1 is a vertical cross-sectional view illustrating a MEMS apparatus according to a first embodiment;

FIG. 2 is a top view illustrating a logic circuit region of the MEMS apparatus according to the first embodiment;

FIG. 3 is a plan view schematically illustrating the relationship between lower and auxiliary electrodes in a MEMS capacitor and a recess region of a substrate in a horizontal direction;

FIGS. 4A to 4C are plan views illustrating a variety of opening patterns of recesses in the recess region;

FIGS. 5A to 5H are vertical cross-sectional views illustrating fabrication processes of the MEMS apparatus according to the first embodiment; and

FIG. 6A and FIG. 6B are vertical cross-sectional views illustrating the MEMS region in the MEMS apparatus according to a second embodiment.

### DETAILED DESCRIPTION

In one embodiment, a MEMS apparatus includes a plurality of recesses opened to a surface, a substrate having an insulator, an air gap, or an insulator and an air gap formed in the recesses, an insulating layer formed on the substrate, and a MEMS device having a signal line formed on the insulating layer, wherein the position of the signal line in a direction parallel to the surface of the substrate overlaps the position of the recess in the direction.

### First Embodiment

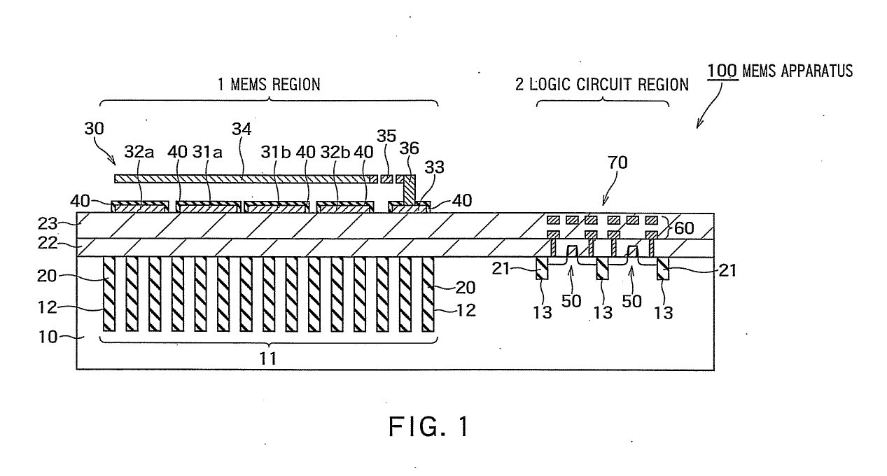

FIG. 1 is a vertical cross-sectional view illustrating a MEMS apparatus 100 in a first embodiment.

The MEMS apparatus 100 includes a MEMS region 1 including a MEMS capacitor 30 and a logic circuit region 2 including a logic circuit 70 for driving the MEMS capacitor 30.

A substrate 10 and insulating layers 22 and 23 are commonly used in the MEMS region 1 and the logic circuit region 2.

The substrate 10 has recesses 12 opened to the surface in the MEMS region 1 and element isolation grooves (shallow Trench Isolations) 13 opened to the surface in the logic circuit region 2. Here, a region, in which the recesses 12 are formed, on the substrate 10 is referred to as a recess region 11. Although the depth of each of the recess 12 and the element isolation groove 13 is not limited, it is preferable that the recess 12 should be deeper than the element isolation groove 13. Incidentally, in the case where local oxidation of silicon (LOCOS) device separation or the like is used for separating transistors 50, described below, no element isolation groove 13 may be formed. The substrate 10 is a silicon substrate made of, for example, a Si crystal.

The MEMS region 1 includes the substrate 10, an embedded insulating film 20 formed inside of each of the recesses 12, the insulating layer 22 formed on the substrate 10, the other insulating layer 23 formed on the insulating layer 22, and the MEMS capacitor 30 formed above the insulating layer 23.

In contrast, the logic circuit region 2 includes the substrate 10, a device separating insulating film 21 formed inside of each of the element isolation grooves 13, the transistors 50 formed in the device region surrounded by the element isolation grooves 13 on the substrate 10, the insulating layer 22 on the substrate 10 incorporating the transistors 50 therein, wiring layers 60 connected to and disposed above the transistors 50, and the insulating layer 23 which incorporates the wiring layers 60 therein and is formed on the insulating layer 22. The transistors 50 and the wiring layers 60 constitute the logic circuit 70. The MEMS capacitor 30 is connected to an uppermost wiring in the wiring layers 60, an electrode, not illustrated, or the like.

The embedded insulating film 20 and the insulating layers 22 and 23 have the function of reducing a parasitic capacitance generated between the MEMS capacitor 30 and the substrate 10. Although the parasitic capacitance becomes smaller as the insulating layers 22 and 23 become thicker, flexure is liable to occur on the substrate 10.

The embedded insulating film 20, the device separating insulating film 21, and the insulating layers 22 and 23 are made of an insulating material such as SiO₂. The embedded insulating film 20 and the insulating layer 22 may be made of the same material integrally with each other.

Each of the transistors 50 includes a gate insulating film on the substrate 10, a gate electrode on the gate insulating film, gate side walls at the side surfaces of the gate electrode, and source and drain regions on both sides of the gate electrode.

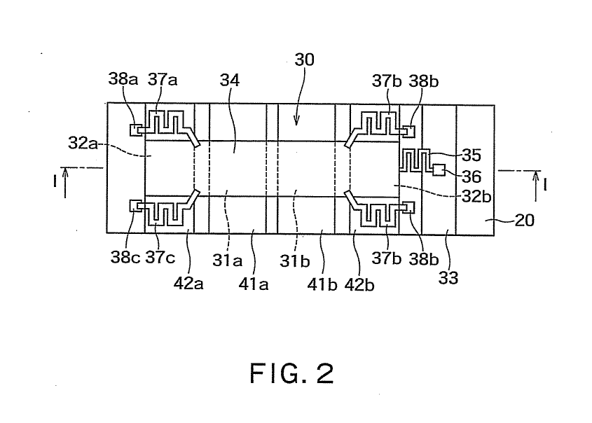

FIG. 2 is a top view illustrating the MEMS region in the MEMS apparatus 100. The cross section of the MEMS apparatus 100, taken along a line I-I, corresponds to the cross section illustrated in FIG. 1.

The MEMS capacitor 30 includes lower electrodes 31a and 31b, auxiliary electrodes 32a and 32b, a wiring 33, an upper electrode 34, a conductive beam 35, an anchor 36, insulating beams 37a, 37b, 37c, and 37d, and anchors 38a, 38b, 38c, and 38d.

The lower electrodes 31a and 31b function as lower electrodes for the MEMS capacitor 30. The lower electrodes 31a and 31b are connected signal lines 41a and 41b, respectively. A signal of, e.g., 0.1 GHz to 100 GHz is supplied to at least either one of the lower electrodes 31a and 31b. For example, a high frequency signal is supplied to the lower electrode 31a whereas the lower electrode 31b is set to a GND potential. Incidentally, the number of lower electrodes is not limited to two, and therefore, it may be one or three or more.

The auxiliary electrodes 32a and 32b are adapted to vary the height of the upper electrode 34. Incidentally, the number of auxiliary electrodes is not limited to two, and therefore, it may be one or three or more. To the auxiliary electrodes 32a and 32b are connected drive lines 42a and 42b, respectively.

Incidentally, the lower electrodes 31a and 31b can serve as electrodes commonly functioning the lower electrodes and the auxiliary electrodes by using a cut-off filter for cutting a signal of a specified frequency. In such a case, neither of the auxiliary electrodes 32a and 32b may be formed.

The wiring 33 is designed to be connected to the upper electrode 34 via the conductive beam 35 and the anchor 36.

The lower electrodes 31a and 31b, the auxiliary electrodes 32a and 32b, and the wiring 33 are made of a conductive material such as Al, and are formed above the insulating layer 22.

Moreover, insulating films 40 are formed in such a manner as to cover the surfaces of the lower electrodes 31a and 31b, the auxiliary electrodes 32a and 32b, and the wiring 33. The insulating films 40 can prevent any short-circuiting between the lower electrodes 31a and 31b, the auxiliary electrodes 32a and 32b, and the wiring 33 and the upper electrode 34. Here, the insulating films 40 are not illustrated in FIG. 2.

The upper electrode 34 is supported above the lower electrodes 31a and 31b and the auxiliary electrodes 32a and 32b via the insulating beams 37a, 37b, 37c, and 37d and the anchors 38a, 38b, 38c, and 38d, and thus, functions as an upper electrode in the MEMS capacitor 30. Incidentally, the size of each of the upper electrode 34 and the lower electrodes 31a and 31b may be freely designed according to the magnitude of an electrostatic capacitance to be required.

The upper electrode 34 is made of a conductive material such as Al. Additionally, the conductive beam 35 is made of a conductive material such as Al. Moreover, the anchor 36 is made of a conductive material such as Al, and it supports the conductive beam 35.

The insulating beams 37a, 37b, 37c, and 37d are made of an insulating material such as SiN. In addition, the anchors 38a, 38b, 38c, and 38d are made of Al.

A clearance defined between the lower electrodes 31a and 31b and the auxiliary electrodes 32a and 32b and the upper electrode 34 is narrowed by applying a voltage between the auxiliary electrodes 32a and 32b and the upper electrode 34, thus varying the electrostatic capacitance generated between the upper electrode 34 and the lower electrodes 31a and 31b. In addition, the clearance defined between the lower electrodes 31a and 31b and the auxiliary electrodes 32a and 32b and the upper electrode 34 can be constantly kept by continuously applying the preset voltage. Upon stoppage of the application of the voltage, the upper electrode 34 returns to its original position by the resiliency of each of the insulating beams 37a, 37b, 37c, and 37d.

Here, the MEMS capacitor 30 may be used as a MEMS switch. For example, exposed regions where the lower electrodes 31a and 31b can be brought into contact with the upper electrode 34 are formed by partly removing the insulating films 40 covering the lower electrodes 31a and 31b. In this manner, the application of the voltage between the auxiliary electrodes 32a and 32b and the upper electrode 34 enables the upper electrode 34 to be driven, thus obtaining a switch in which the lower electrodes 31a and 31b can be brought into contact with and conduction to the upper electrode 34.

The structure of the MEMS capacitor 30 is not limited to the above-described structure. For example, both of an upper electrode and a lower electrode may be movable, and alternatively, a movable electrode may be interposed between a fixed upper electrode and a fixed lower electrode.

A wiring or a part of the logic circuit 70 in the logic circuit region 2 or a passive device may be formed by using a wiring which is formed simultaneously with the MEMS capacitor 30 or connected to the MEMS capacitor 30.

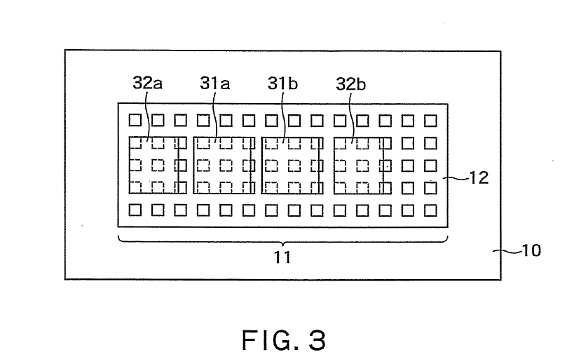

FIG. 3 is a plan view schematically illustrating the relationship between the lower electrodes 31a and 31b and the auxiliary electrodes 32a and 32b in the MEMS capacitor 30 and the recess region 11 on the substrate 10 in a horizontal direction (i.e., a direction parallel to the surface of the substrate 10).

Since the embedded insulating film 20 is formed inside of the recess 12, the average thickness of the insulating film in the recess region 11 consisting of the insulating layers 22 and 23 and the embedded insulating film 20 is greater than that of the insulating film in the other region consisting of only the insulating layers 22 and 23. Therefore, the MEMS capacitor 30 is formed above the recess region 11, thereby reducing a parasitic capacitance generated between the MEMS capacitor 30 and the substrate 10.

It is preferable that the position of the electrode in which the signal is supplied onto the insulating layer 23 should vertically overlap the recesses 12 so as to effectively reduce the parasitic capacitance. FIG. 3 illustrates the overlap between the lower electrodes 31a and 31b and the auxiliary electrodes 32a and 32b, and the recesses 12.

The higher the frequency of the signal to be supplied to the electrode, the greater the influence of the parasitic capacitance. In view of this, the horizontal position of the electrode in which the signal of the high frequency is supplied in the electrode to which the signal is supplied on the insulating layer 23 is required to overlap the position of the recesses 12.

For example, in the case where the MEMS capacitor 30 is an RF-MEMS device in which a signal having a frequency of several hundreds MHz or higher is supplied to the lower electrode 31a, the horizontal position of at least the lower electrode 31a is required to overlap the position of the recesses 12.

Incidentally, the recess region 11 may be present also under signal lines to be connected to the MEMS capacitor 30, like the signal lines 41a and 41b.

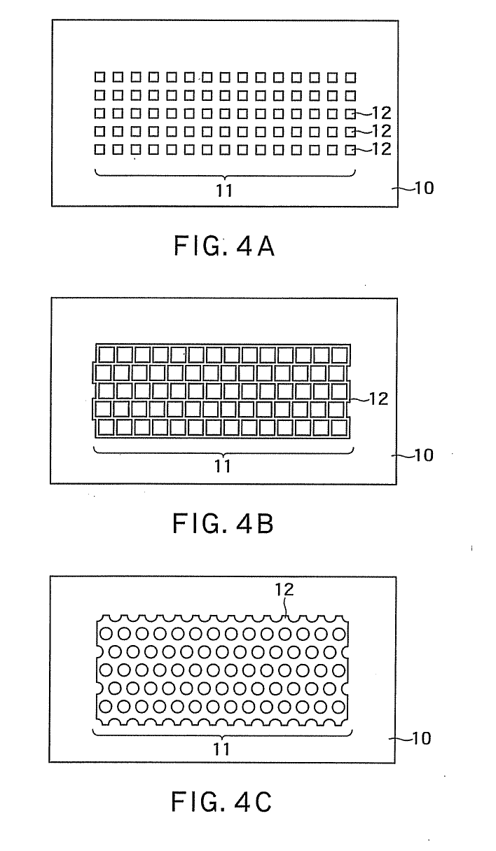

FIG. 4A, FIG. 4B and FIG. 4C are plan views illustrating a variety of opening patterns of the recesses 12 in the recess region 11.

FIG. 4A illustrates the opening pattern of the recesses 12 in which the negative and the positive are reversed from that illustrated in FIG. 3. The opening pattern of the recesses 12 is a split pattern consisting of a plurality of isolated areas, thereby forming a grid pattern on the substrate 10 inside of the recess region 11. In this case, no island area surrounded by the recesses 12 on the substrate 10 is formed, and therefore, the recesses 12 may be through holes reaching the back surface of the substrate 10.

FIG. 4B illustrates an opening pattern of grid-like recesses 12 zigzagged in row. Moreover, FIG. 4C illustrates a grid-like opening pattern of circular recesses 12 on the substrate 10. As illustrated in FIG. 4A, FIG. 4B and FIG. 4C, the opening patterns of the recesses 12 are not limited.

Hereinafter, a description will be given of one example of a fabricating method for the MEMS apparatus 100 according to the first embodiment.

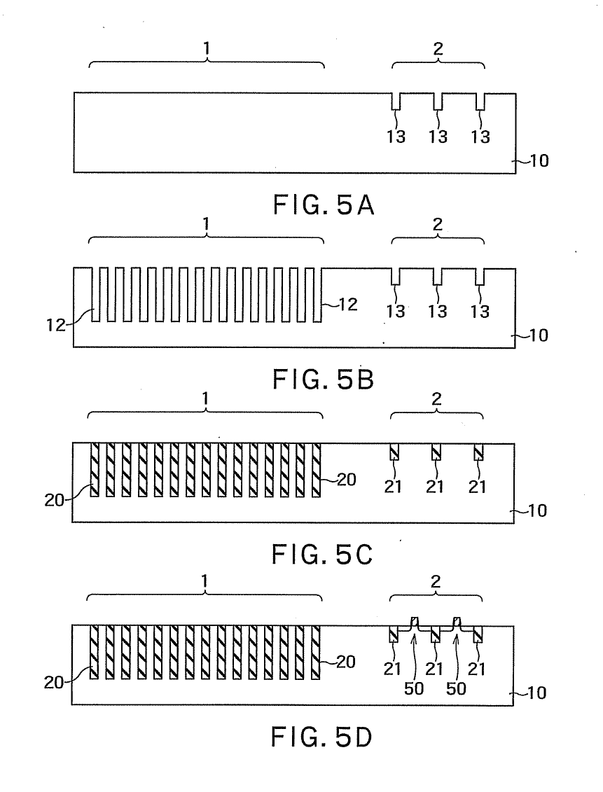

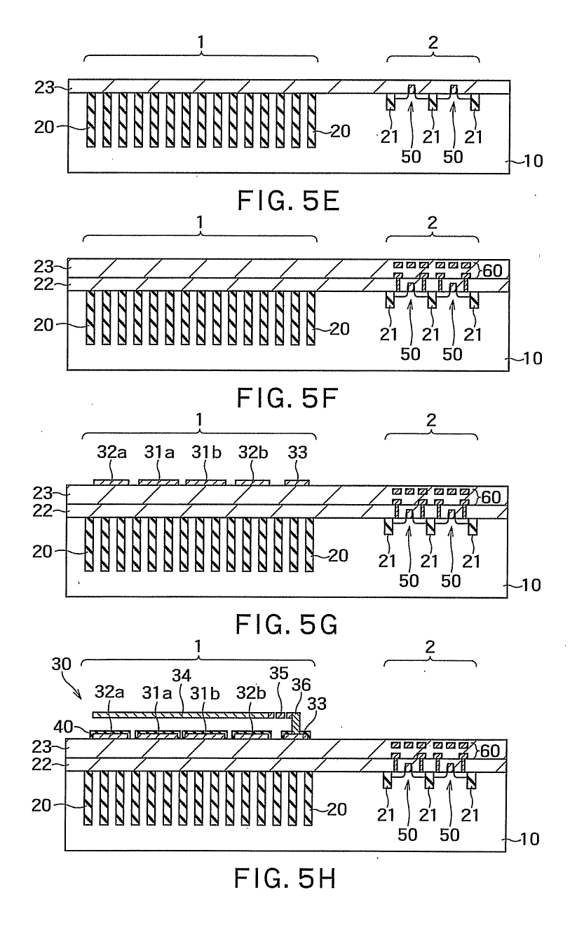

FIGS. 5A to 5H are vertical cross-sectional views illustrating fabrication processes of the MEMS apparatus 100 according to the first embodiment.

First, as illustrated in FIG. 5A, the element isolation grooves 13 are formed in the logic circuit region 2 on the substrate 10.

Description will be made on one example of a forming method for the element isolation grooves 13. First, a photoresist, not illustrated, having the pattern of the element isolation grooves 13 on the substrate 10 via a mask member, not illustrated, such as a silicon nitride film or a silicon oxide film. Then, the mask member is patterned by anisotropic etching such as Reactive Ion Etching (RIE). Next, after the photoresist is removed, the substrate 10 is etched in about 300 nm by using the mask member as a mask, thereby obtaining the element isolation grooves 13. Here, when the transistor 50 is separated by the LOCOS device separation, no element isolation groove 13 is formed.

Next, as illustrated in FIG. 5B, the recesses 12 are formed in the MEMS region 1 on the substrate 10.

One example of the forming method for the recesses 12 will be described below. First, a photoresist having the pattern of the recesses 12, not illustrated, is formed on the substrate 10 via a mask member, not illustrated, and then, the mask member is processed by anisotropic etching such as the RIE. Subsequently, the photoresist is removed, and thereafter, the substrate 10 is etched in about 1000 nm to 10000 nm by using the mask member as a mask, thereby obtaining the recesses 12. At this time, the mask member used in forming the grooves 13 may be used as it is.

Here, the element isolation grooves 13 may be formed before the recesses 12 are formed. The recesses 12 and the element isolation grooves 13 are formed, followed by wetting, heat annealing, or the like, as required.

Subsequently, as illustrated in FIG. 5C, the embedded insulating film 20 and the device separating insulating film 21 are formed inside of the recess 12 and the element isolation grooves 13, respectively.

One example of the forming method for the embedded insulating film 20 and the device separating insulating film 21 will be described below. First, an insulating film such as a silicon oxide film is formed over the entire surface of the substrate 10 in such a manner as to be embedded inside of each of the recesses 12 and the element isolation grooves 13. The thickness of the insulating film depends on a film formation condition; for example, it is 500 nm or more. The film formation condition may be varied during the film formation of the insulating film.

At this time, although the insulating film is formed such that it is sufficiently embedded inside of the element isolation groove 13, it may not always be sufficiently embedded inside of the recess 12. The region having no insulating film embedded inside of the recess 12 serves as an air gap having a high dielectric constant, thus effectively reducing the parasitic capacitance generated between the MEMS capacitor 30 and the substrate 10.

Next, the insulating film is subjected to flattening such as the Chemical Mechanical Polishing (CMP), so that the outer portion of each of the recesses 12 and the element isolation grooves 13 is removed, thereby obtaining the embedded insulating film 20 and the device separating insulating film 21, respectively. At this time, the mask member, which has been used in forming the grooves 13 and the recesses 12, may be used as a stopper film. Thereafter, the mask member is removed by wet-etching such as thermal phosphate treatment.

Here, the insulating film may be embedded in the recess 12 in a process different from that in which the insulating film is embedded in the element isolation groove 13. Alternatively, the element isolation groove 13 may be formed after the formation of the embedded insulating film 20, or the recess 12 may be formed after the formation of the device separating insulating film 21.

Thereafter, as illustrated in FIG. 5D, the transistors 50 are formed in the device region surrounded by the element isolation grooves 13 on the substrate 10 by using a normal transistor process.

Subsequently, as illustrated in FIG. 5E, the insulating layer 22 is formed over the entire surface on the substrate 10. Here, the insulating layer 22 and the embedded insulating film 20 may be formed integrally with each other. In this case, the device separating insulating film 21 is selectively formed by masking the opening of the recess 12 in forming the device separating insulating film 21, such that the insulating film is formed in the recess 12 and on the substrate 10 in forming the insulating layer 22.

Next, as illustrated in FIG. 5F, the other insulating layer 23 incorporating the wiring layers 60 therein is formed on the insulating layer 22 by a known method. The insulating layer 23 may include a plurality of kinds of insulating films. A silicon oxide film having a thickness of about 1 μm to 20 μm, for example, exists on the uppermost wiring of the wiring layers 60.

Although the wiring of the wiring layer 60 may be disposed above the recess region 11, it is preferable that it should not be disposed because there is a possibility of an increase in parasitic capacitance generated between the MEMS capacitor 30 and the substrate 10.

Subsequently, as illustrated in FIG. 5G, the lower electrodes 31a and 31b, the auxiliary electrodes 32a and 32b, and the wiring 33 are formed on the insulating layer 23. A metallic film is formed over the entire surface of the insulating layer 23, followed by patterning, thereby obtaining the lower electrodes 31a and 31b, the auxiliary electrodes 32a and 32b, and the wiring 33.

Next, as illustrated in FIG. 5H, after the formation of the insulating film 40 covering the lower electrodes 31a and 31b, the auxiliary electrodes 32a and 32b, and the wiring 33, the upper electrode 34, the conductive beam 35, and the anchor 36 are formed, thus obtaining the MEMS capacitor 30.

One example of the forming method for the insulating film 40, the upper electrode 34, the conductive beam 35, and the anchor 36 will be described below. First, the insulating film is formed in such a manner as to cover the lower electrodes 31a and 31b, the auxiliary electrodes 32a and 32b, and the wiring 33, followed by patterning, thereby obtaining the insulating film 40. Next, a metallic film is formed on the insulating film 40 via a sacrificial layer, not illustrated, followed by patterning, thereby obtaining the upper electrode 34, the conductive beam 35, and the anchors 36 and 38a to 38d. Subsequently, the insulating film is formed over the entire surface, followed by patterning and etching, thereby obtaining the insulating beams 37a to 37d. Thereafter, the sacrificial layer is removed, thus achieving the MEMS capacitor 30 in which the upper electrode 34 is disposed in the air whereas the lower electrodes 31a and 31b are fixed.

Thereafter, a sealing structure for sealing the MEMS capacitor 30 via a thin film dome or the like may be formed so as to protect the MEMS capacitor 30. The MEMS capacitor 30 and the logic circuit 70 in the logic circuit region 2 may be connected by using a method for performing a contact process after the formation of the MEMS capacitor 30 or a method for connecting the lower electrodes 31a and 31b, the auxiliary electrodes 32a and 32b, and the wiring 33 to a contact formed before the formation of the MEMS capacitor 30.

### Second Embodiment

A second embodiment is different from the first embodiment in forming an air gap inside of a recess 12. Here, the same description as that in the first embodiment will not be repeated or will be simplified below.

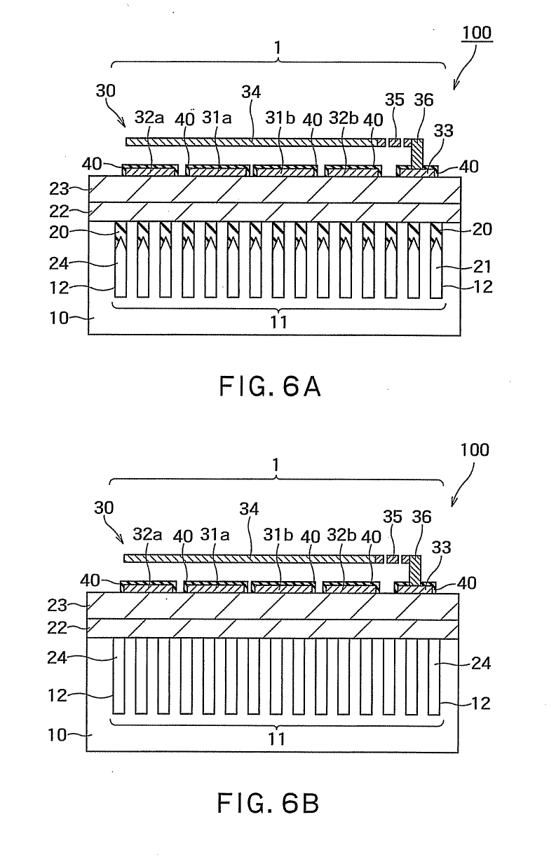

FIG. 6A and FIG. 6B are vertical cross-sectional views illustrating a MEMS region 1 in a MEMS apparatus 100 according to the second embodiment.

FIG. 6A illustrates a structure in which an embedded insulating film 20 is formed only in an upper portion of the recess 12. For example, in a process in which an insulating film serving as a material for the embedded insulating film 20 and a device separating insulating film 21, the process being illustrated in FIG. 5C in the first embodiment, the film formation is stopped at the time when the insulating film is sufficiently embedded inside of a element isolation groove 13, thereby obtaining the structure illustrated in FIG. 6A.

A region having no embedded insulating film 20 formed at a lower portion of the recess 12 serves as an air gap 24. The air gap has a high dielectric constant. Thus, the formation of the air gap can effectively reduce a parasitic capacitance generated between a MEMS capacitor 30 and a substrate 10.

FIG. 6B illustrates a structure in which no embedded insulating film 20 is formed inside of the recess 12 whereas the air gap 24 occupies the recess 12. For example, the device separating insulating film 21 is selectively formed by masking the opening of the recess 12 in forming the device separating insulating film 21, and thereafter, an insulating layer 22 is formed under a bad coating condition, thus obtaining the structure in which no insulating film is contained inside of the recess 12.

With the above-described structure, the air gap 24 having a high dielectric constant occupies the recess 12, thus more effectively reducing the parasitic capacitance generated between the MEMS capacitor 30 and the substrate 10.

In the first and second embodiments, the electrode, to which the signal is supplied, on the insulating layer 23 overlaps the recesses 12, and therefore, the parasitic capacitance generated between the MEMS capacitor 30 and the substrate 10 can be reduced. The same goes for the case where the MEMS capacitor 30 is replaced with another MEMS device. In addition, in the case where the MEMS capacitor 30 is used as the MEMS device, the capacitor characteristics can be improved.

Moreover, it is possible to reduce the parasitic capacitance generated between the MEMS device and the substrate 10 without forming a thick insulating layer between the MEMS device such as the MEMS capacitor 30 and the substrate 10, thus avoiding the issue of occurrence of flexure on the substrate caused by a difference in stress between a thick insulating layer and the substrate.

Additionally, no thick insulating layer is interposed between the MEMS device and the substrate 10, and thus, a contact plug for use in connecting the MEMS device and a transistor 50 is reduced in depth, and therefore, it can be readily formed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An MEMS apparatus comprising:
a substrate having a plurality of recesses opened to a surface and an insulating material, an air gap or an insulating material and an air gap formed in the recesses;
an insulating layer formed on the substrate; and
a MEMS device having a signal line formed on the insulating layer,
wherein the position of the signal line in a direction parallel to the surface of the substrate overlaps the position of the recess in the direction.

2. The apparatus of claim 1, wherein the MEMS device has an upper electrode thereon,
the recesses being formed at portions at which the position of the signal line in the direction parallel to the surface of the substrate overlaps the upper electrode in the MEMS device.

3. The apparatus of claim 1, wherein the signal line is a signal line to which a signal of 0.1 GHz to 100 GHz is supplied.

4. The apparatus of claim 1, wherein the opening pattern of the plurality of recesses is a grid pattern or a split pattern.

5. The apparatus of claim 1, wherein the plurality of recesses are through holes reaching the back surface of the substrate.

6. The apparatus of claim 1, wherein the insulating material and the insulating layer are made of the same material.

7. The apparatus of claim 6, wherein the insulating material and the insulating layer are formed of a silicon oxide film.

8. The apparatus of claim 1, wherein the MEMS device is a MEMS capacitor.

9. The apparatus of claim 1, wherein the MEMS device is a MEMS switch.

10. The apparatus of claim 1, further comprising:
a logic circuit for driving the MEMS device, formed in a region, in which no recess is included, on the substrate.

11. The apparatus of claim 10, wherein the substrate has element isolation grooves in the region,
the recess being deeper than the element isolation groove.

12. The apparatus of claim 11, wherein the MEMS device has an upper electrode thereon,
the recesses being formed at portions at which the position of the signal line in the direction parallel to the surface of the substrate overlaps the upper electrode in the MEMS device.

13. The apparatus of claim 11, wherein the signal line is a signal line to which a signal of 0.1 GHz to 100 GHz is supplied.

14. The apparatus of claim 11, wherein the opening pattern of the plurality of recesses is a grid pattern or a split pattern.

15. The apparatus of claim 11, wherein the plurality of recesses are through holes reaching the back surface of the substrate.

16. The apparatus of claim 11, wherein a device separating insulating film is embedded in the device separating groove.

17. The apparatus of claim 16, wherein the device separating insulating film is made of the same material as those of the insulating material and the insulating layer.

18. The apparatus of claim 1, wherein a part of the signal line is formed above the recesses of the substrate.

19. The apparatus of claim 1, wherein the MEMS device has a plurality of lower electrodes, and parts of the lower electrodes are formed above the recesses, respectively.

20. The apparatus of claim 1, wherein the MEMS device has a plurality of lower electrodes, and at least a part of one of the lower electrodes is formed above the recesses.
